(19) United States
(12) Patent Application Publication
(10) Pub. No.: US 2003/0234660 A1
(43) Pub. Date: Dec. 25, 2003

(54) Direct landing technology for wafer probe

(76) Inventor: Sunil K. Jain, Folsom, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/179,622

(22) Filed: Jun. 24, 2002

(51) Int. Cl. G01R 31/26

(52) U.S. Cl. 324/765

(57) ABSTRACT

Embodiments of the invention provide a direct landing technology for improved wafer testing of semiconductor dies that is scalable to next generation packaging. In particular, the package drawing or custom drawing of a semiconductor die under test is infused on the printed circuit board of the sort interface unit. After decoupling capacitors are mounted and a semiconductor die footprint fabricated on printed circuit board sort interface unit, probe head may be directly sandwiched between semiconductor die under test and printed circuit board sort interface unit. Since the package information is infused on the printed circuit board sort interface unit, the need for a multi layer ceramic space transformer, sockets and so forth are eliminated and high speed testing facilitated. The manufacturing process becomes extremely simplified, low cost, and more reliable due to significantly reduced variable dependencies.

### BACKGROUND

1. Field

The invention relates to the field of semiconductor device testing and more particularly to wafer probing technology.

2. Background Information

Semiconductor devices are typically tested at the wafer level to evaluate their functionality. The process in which devices in a wafer are tested is commonly referred to as “wafer sort.” Testing and determining design flaws at the wafer level offers several advantages. For example, it allows designers to evaluate the functionality of new devices during development. Increasing packaging costs also make wafer sorting a viable cost saver, in that reliability and functionality of each die on a wafer may be tested before incurring the higher costs of packaging. Measuring reliability also allows the performance of the production process to be evaluated and production consistency rated, where the performance of a die is downgraded because that die's performance did not meet the expected criteria.

Wafer testing and sorting typically involves the use of probing technology wherein a probe engages the bond pads on a die under test so as to connect the pads to a testing apparatus. FIG. 1 illustrates a conventional testing configuration 100 for wafer (i.e. die) under test 102 including probe head 104, multi layer ceramic (MLC) space transformer 106, printed circuit board sort interface unit 108 with MLC footprint (not shown) and testing apparatus 110. Probe head 104 sits below and in contact with the wafer under test 102. During testing, wafer under test 102 is positioned so as to precisely align the bond pads of die 102 with probe head 104.

In particular, space transformer 106 interconnects probe head 104 to printed circuit board sort interface unit 110. Space transformer 106 is typically formed from a multi layer ceramic substrate designed for the specific die under test configuration. Space transformer 106 is interconnected 112 to multi layer printed circuit board 108 via socket or direct solder. In a socket interconnection, rigid pins of space transformer 106 are received by resilient socket elements of printed circuit board sort interface unit 108 or vice versa.

Conventional test assemblies fail to optimize electrical performance and/or are expensive to fabricate. In particular, from a high-speed signal integrity point of view, conventional multi layer ceramic space transformers and the contemporary probes experience difficulty tackling fast edge rates and bandwidths of the signals propagating through them. Consequently, it requires a great deal of effort and resources to design and optimize an electrically clean package layout. If the same layout is not used in the multi layer ceramic space transformer, all or substantially all of the work that was done by the packaging group in providing an optimal layout is lost, and the die can not be tested at full functional speeds and bandwidths, resulting in losses due to packaging of bad die.

Moreover, conventional buckling beam vertical probe heads and test assemblies are generally not scalable or portable to next generation processes or packaging techniques. Additionally, contemporary probes for integrated circuits are expensive to fabricate. Because wafer pins are typically microscopic in dimension, specially machined precise microscopic level probes are required. Correspondingly, the space transformer needs to be specially designed for the particular test configuration. With each new die design to be tested, a new sort interface board must be designed and manufactured. This is both time-consuming and costly.

### BRIEF DESCRIPTION OF THE DRAWINGS

FIG. 1 illustrates a block diagram of an embodiment of prior art wafer probing technology.

FIG. 2 illustrates a block diagram of an embodiment of wafer probing technology in accordance with the present invention.

FIG. 3 illustrates a process flowchart for manufacturing a printed circuit board sort interface unit according to one embodiment of the invention.

FIG. 4 illustrates a top side view of an embodiment of a C4 bond pad configuration on semiconductor die under test.

FIG. 5 illustrates an embodiment of printed circuit board sort interface unit after package drawing has been infused.

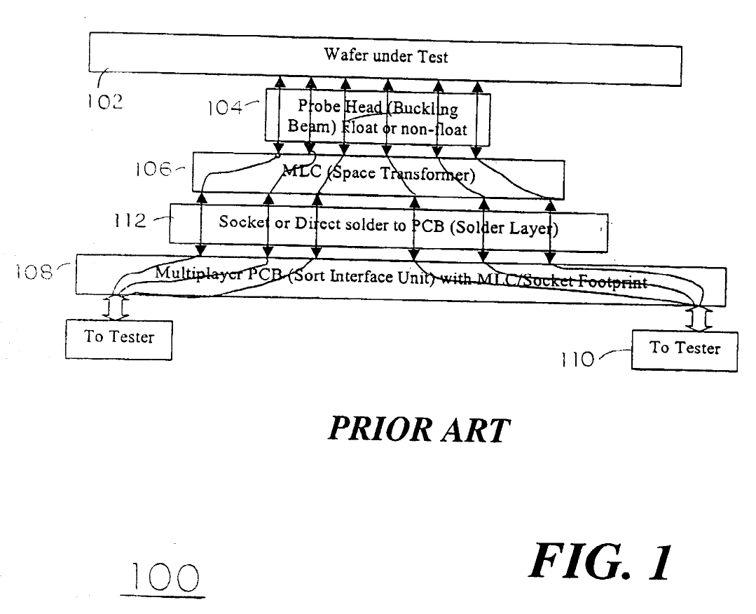

### DETAILED DESCRIPTION

Embodiments of the invention provide a direct landing technology for improved wafer testing of semiconductor dies that is scalable to next generation packaging. In particular, the package drawing or custom drawing of a semiconductor die under test is infused on the printed circuit board of the sort interface unit. After decoupling capacitors are mounted and a semiconductor die footprint fabricated on printed circuit board sort interface unit, probe head may be directly sandwiched between semiconductor die under test and printed circuit board sort interface unit. Since the package information is infused on the printed circuit board sort interface unit, the need for a multi layer ceramic space transformer, sockets and so forth are eliminated and high speed testing facilitated. The manufacturing process becomes extremely simplified, low cost, and more reliable due to significantly reduced variable dependencies.

In the following detailed description of the embodiments, reference is made to the accompanying drawings that show, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

The package drawing can be directed to a single or multiple semiconductor die. In particular, one skilled in the art will recognize that the present invention may be applied at the wafer-scale, multiple die, or single die level. As used herein, the term “die” may denote a single die (chip) from a wafer or a plurality of dies, up to an entire wafer if wafer-scale integration is employed for the unit under test. Moreover, as used herein, the term “wafer scale” is not limited to traditional wafers but encompasses any semiconductive material layer on which a large plurality of discrete active devices may be fabricated, including but not limited to silicon-on-insulator (SOI) and silicon-on-sapphire (SOS) structures. Additionally, although references are made to the term “printed circuit board,” it should be understood that the printed circuit board element can be any suitable substrate upon which terminals can be formed and electronic components connected to. Furthermore, although references are made to the term “package drawing,” it should be understood that the package drawing might be any suitable custom made special or generic layout to make connections between the semiconductor die to the tester. Although references are made to the term “bumps,” it should be understood that the term may encompass balls, cylinders, cuboids, pyramids or cones (including truncated such structures). Furthermore, the term “bond pad” is intended to include and encompass all suitable terminal structures to which a diffusion bond may be made, including both elevated and recessed bond pads as well as flat, concave or convex bond pads and other terminal structures; and bond pads may be formed of gold-compatible materials. Additionally, the term “footprint” is intended to include and encompass contact pattern(s) or pin-out(s) of the die under test.

For illustrative purposes, embodiments of the present invention are described using controlled collapse chips connection (C4) packaging technology. It is to be appreciated that the invention need not be limited to C4 packaging. Instead, the process described above can be used and is contemplated for use in any process where conductive bumps are used in assembly technology. The other types of processes include but are not limited to wire bonding (WB) and tape automated bonding (TAB). During wafer sorting the probing features of the probe card contact the solder bumps.

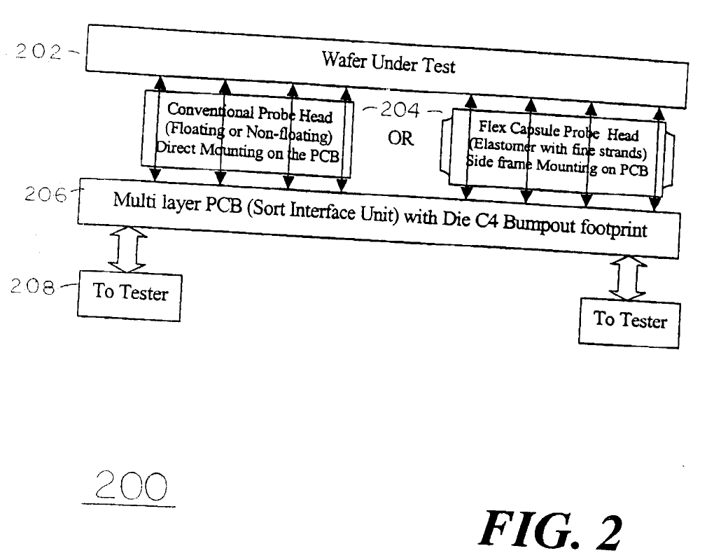

FIG. 2 illustrates a block diagram of an embodiment 200 of a direct landing test configuration for wafer (die) under test 202 including probe head 204, sort interface unit 206 and test device 208. Sort interface unit 206 provides a direct interface between probe head 204 and test device 208. In particular, probe head 204 is disposed directly between wafer under test 202 and sort interface unit 206. The type of probe head utilized is not critical to the present invention. For example, probe head 204 may be a conventional buckling beam (e.g., floating or non-floating) probe or, specially manufactured probe head.

In particular, semiconductor die under test 202 with active and optionally passive components, as well as circuit traces, vias and other conductive paths as known in the art, is positioned on top of probe head 204 which is positioned on top of die C4 bumpout footprint on sort interface unit 602. Semiconductor die under test 202 is aligned with the die C4 bumpout footprint on sort interface unit 602 (with the die and sort interface unit planes being substantially parallel and die and substrate electrical contacts being coincident).

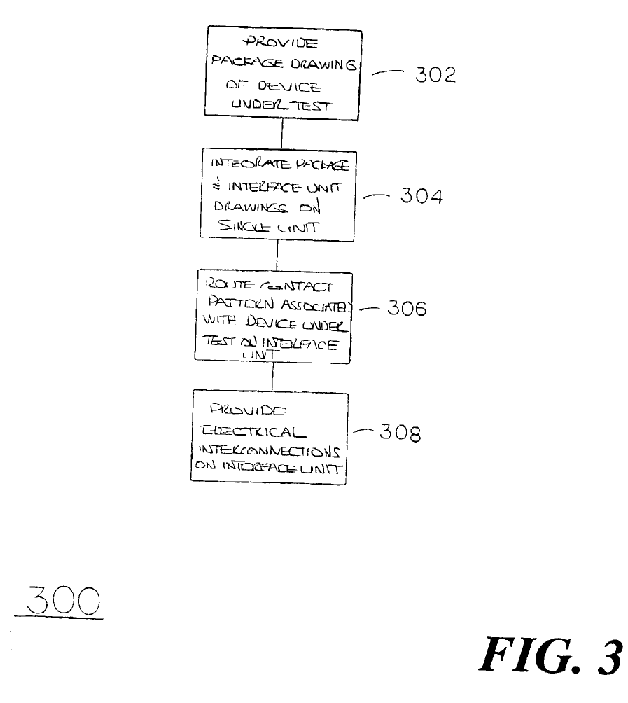

FIG. 3 illustrates a process flowchart 300 for manufacturing a sort interface unit according to one embodiment of the invention. Sort interface unit provides direct routing of signals between a test device and a probe device such that the probe device is directly disposed between the semiconductor device and sort interface unit. A package drawing associated with the semiconductor device is initially provided (step 302). Package and interface unit drawings are initially integrated together on a single interface unit, such as a printed circuit board (step 304). In particular, once package drawing associated with semiconductor die is available, the package drawing is infused. on multi-layer printed circuit board during the design stage. The package information to be infused onto the multi-layer printed circuit board sort interface unit in step 304 may be generated from a package drawing prepared in a conventional manner during the manufacture process by a packaging group. The purpose of the package is to take the signal from the wafer level microscopic bump out to a larger fan out. In particular, the package provides a interconnect pitch that is wider that the spacing of bond pads on a semiconductor die.

In a typical operation, infusing the package drawing on the printed circuit board may take only approximately 1-2 hours. Printed circuit board sort interface unit thus includes a bump out that matches the die under test rather than the multi layer ceramic space transformer as in the prior art. The contact structures on the printed circuit board sort interface unit are arranged at the same or substantially the same pitch as the bond pitch on the die under test.

Referring to FIG. 3, a contact pattern associated with the semiconductor device is then routed on the sort interface unit (step 306). For example, a footprint of die under test is formed on sort interface unit. In a typical implementation, a C4 bump out footprint is routed and fabricated on sort interface unit. Probe head 204 contacts portions of the footprint of die under test. The footprint contains connections interfacing the sort interface unit with die under test.

Electrical interconnections are then provided on the sort interface unit that routes signals from the test device to the probe device (step 308). In particular, components, such as decoupling capacitors, are mounted on sort interface unit (step 308). Interfacing of the circuitry in sort interface unit 206 with the circuitry of the test system may be accomplished by conventional means and is not critical to embodiments of the present invention.

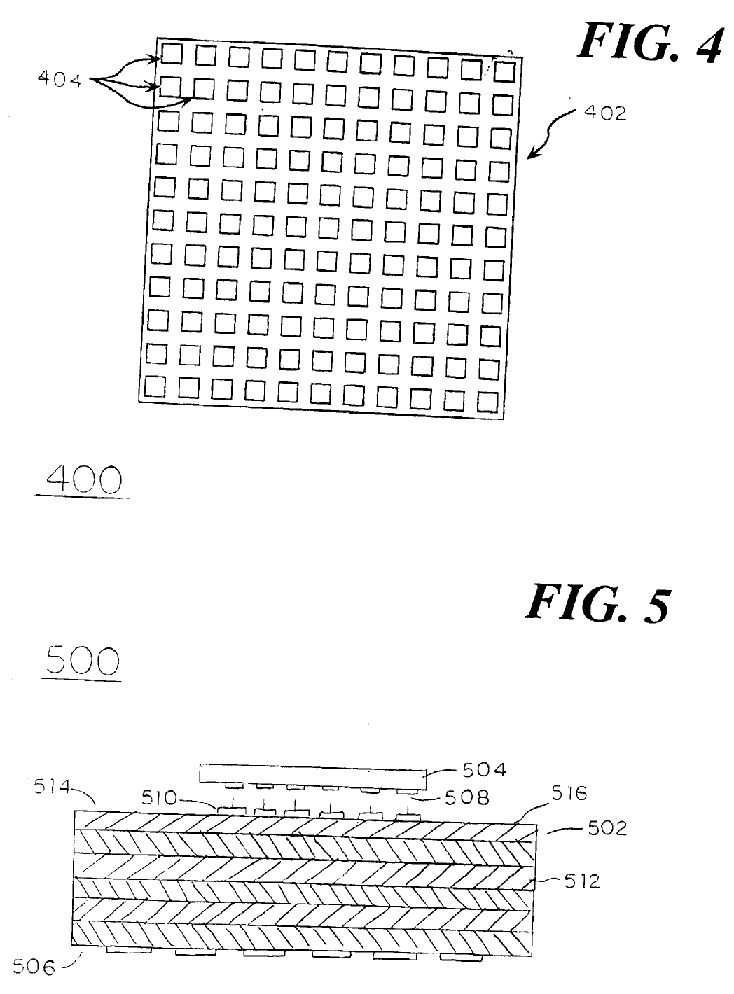

FIG. 4 illustrates a top side view of an embodiment 400 of a C4 bond pad configuration on semiconductor die 402. Bond pads 404 of semiconductor die 402 are formed along the top of the entire die 402 so that bond pads 404 now reside directly over the active circuitry region of die 402. By forming bond pads 404 in both the center and periphery of semiconductor die 402, more bond pads 404 can be placed across the surface of device 402 than can be placed only within the peripheral region. In addition, active circuitry which underlies bond pads 404 can be directly coupled to its nearest bond pad 504 using relatively short interconnect lines. This minimizes the resistive, capacitive, and inductive effects associated with routing interconnect lines over long distances, improving speed performance.

In a typical implementation, a semiconductor die 402 has a plurality of solder bumps disposed on its lower (as viewed) surface, such as in an array. After infusion of the package drawing, printed circuit board sort interface unit with C4 bumpout footprint has a corresponding plurality of contact structures disposed on its upper surface. The distal ends of these contact structures are arranged at the same pitch (spacing) as the solder bumps.

Referring to FIG. 5, an embodiment 500 of printed circuit board sort interface unit 502 after package drawing has been infused is illustrated. Semiconductor die under test 504 has a plurality of solder bumps 508 disposed on its lower surface. After infusion of the package drawing, printed circuit board sort interface unit 502 with footprint has a corresponding plurality of contact structures 510 disposed on its upper surface. The ends of these contact structures 510 are arranged at substantially the same pitch as bumps 508. Printed circuit board sort interface unit 502 is formed of alternating layers of insulating material and patterned conductive material. The lower surface 506 of printed circuit board sort interface unit 502 is provided with a plurality of contact pads 504 which are disposed at a larger spacing than the contact structures 506 on upper surface 514.

Various patterns and openings are formed within the metal layers within printed circuit board sort interface unit 502 in order to effectively route signals from tester, through printed circuit board sort interface unit 502 to die under test. In particular, a plurality of conductive layers 512 may be formed on printed circuit board sort interface unit 502 to route all different types of electrical signals from contact pads 504 to contact structures 510. It is important to note that sort interface unit 502 may contain a plurality of conductive layers for routing purposes depending upon the complexity of interconnection needed to the specific device being manufactured. In particular, conductive layers 512 route electrical signals, such as logic signals, or active analog signals, between tester and die under test. Additionally, ground layers are used to route ground signals to die under test. Printed circuit board sort interface unit also includes one or more layers for routing one or more power voltage supply levels for one or more voltage supplies that are needed by die under test. Generally, each conductive layer within printed circuit board sort interface unit performs a specific routing function of routing digital/analog electrical signals, routing ground voltages, or routing power supply voltages.

As shown in FIG. 3, a die bumpout footprint is formed on printed circuit board sort interface unit (step 306). Referring to FIG. 5, in a typical implementation, a C4 bumpout footprint is routed and fabricated on sort interface unit 502. The footprint contains connections interfacing sort interface unit 502 with die under test 504. A plurality of gold bumps 510 is formed on a non-electrically conductive portion 516 of printed circuit board sort interface unit 502 by conventional means known in the art. Bumps 510 are located at the ends of circuit traces extending to the periphery of the portion of sort interface unit 502. Gold bumps 510 are formed through bump forming processes known in the art. The compositions of the gold bumps may include, but are not limited to gold bond wire, as well as other gold-based alloys as known in the art.

After die bumpout footprint is routed on sort interface unit 502, semiconductor die under test 504 has a plurality of bond pads in the same configuration as gold bumps 510 on sort interface unit 502. Thus, when semiconductor die under test 504 is placed on sort interface unit 502, the bond pads and the gold bumps match. Other alignment methods known in the art may also be employed.

Referring to FIG. 2, in operation, probe head 204 contacts solder bumps on integrated circuit device during a wafer sort. Probe head 204 is thus directly sandwiched between the die under test 202 and sort interface unit 206. Probe head 204 directly lands on printed circuit board sort interface unit 206 instead of multi layer ceramic space transformer. One or more dies are thus are in communication with printed circuit board, filling a “footprint” on sort interface unit 206. During wafer sort, probe tips 24 touch down on solder bumps which are part of die under test 202. After testing, probing features 22 disengage die under test 202.

The above description of illustrated embodiments of the invention is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A process for testing a semiconductor device, comprising:
forming an interface that provides direct routing of signals between a test device and a probe device such that the probe device is directly disposed between the semiconductor device and the interface.

2. The process claimed in claim 1 wherein forming an interface that provides direct routing of signals between a test device and a probe device such that the probe device is directly disposed between the semiconductor device and the interface, further comprising:
providing a package drawing associated with the semiconductor device;
infusing the package drawing on the interface;
routing a contact pattern associated with the semiconductor device on the interface; and
providing electrical interconnections on the interface that routes signals from the test device to the probe device.

3. The process claimed in claim 1 wherein the semiconductor device comprises one or more semiconductor dies.

4. The process claimed in claim 1 wherein the probe device comprises a probe head.

5. The process claimed in claim 1 wherein the interface comprises a multi layer substrate.

6. The process claimed in claim 1 wherein the interface comprises a printed circuit board.

7. The process claimed in claim 2 wherein providing electrical interconnections on the interface for routing signals from a test device to the probe device further comprising:
disposing at least one decoupling capacitor on the interface.

8. The process claimed in claim 2 wherein providing a package drawing associated with the semiconductor device further comprising:
providing an interconnection pitch on a first surface of interface that is compatible with the interconnection pitch of bond pads on the semiconductor device.

9. The process claimed in claim 8 wherein providing an interconnection pitch on a first surface of interface that is compatible with the interconnection pitch of bond pads on the semiconductor device further comprising:
providing an interconnection pitch on the first surface of interface that is similar or substantially similar to the interconnection pitch of bond pads on the semiconductor device.

10. The process claimed in 8 wherein probe device engages with contact pads on the semiconductor device during testing.

11. The process claimed in claim 2 wherein routing a contact pattern associated with the semiconductor device on the substrate further comprises:
routing a contact pattern compatible with collapse chips connection packaging technology.

12. The process claimed in claim 2 wherein the package drawing comprises a generic drawing.

13. The process claimed in claim 2 wherein the package drawing comprises a custom drawing.

14. An apparatus for testing a semiconductor device, comprising:
a probe device;
a test device; and
an interface unit that directly routes signals between the test device and the probe device such that the probe device is directly disposed between the semiconductor device and the interface unit.

15. The apparatus claimed in claim 14 wherein the interface unit is disposed between the probe device and test device.

16. The apparatus claimed in claim 14 wherein the interface unit further comprises:
an upper surface including a plurality of ball bumps disposed in a contact pattern compatible with the probe device and semiconductor device; and
a lower surface including a plurality of contacts for receiving signals from the testing device.

17. The apparatus claimed in claim 16 wherein the plurality of ball bumps disposed on the upper surface of the interface unit are electrically connected to the probe device during testing.

18. The apparatus claimed in claim 16 wherein the interface unit is formed partly based upon on a package drawing associated with the semiconductor device.

19. The apparatus claimed in claim 16 wherein the interface unit further comprises electrical interconnections that route signals between the test device and the probe device.

20. The apparatus claimed in claim 14 wherein the semiconductor device comprises one or more semiconductor dies.

21. The apparatus claimed in claim 14 wherein the probe device comprises a probe head.

22. The apparatus claimed in claim 14 wherein the interface unit comprises a multi layer substrate.

23. The apparatus claimed in claim 14 wherein the interface unit comprises a printed circuit board.

24. The apparatus claimed in claim 14 wherein the electrical interconnections further comprise:
at least one decoupling capacitor.

25. The apparatus claimed in claim 14 wherein the first surface includes an interconnection pitch that is compatible with the interconnection pitch of bond pads on the semiconductor device.

26. The apparatus claimed in claim 25 wherein the first surface includes an interconnection pitch that is similar or substantially similar to the interconnection pitch of bond pads on the semiconductor device.

27. The apparatus claimed in claim 14 wherein probe device engages with contact pads on the semiconductor device during testing.

28. The apparatus claimed in claim 16 wherein the upper surface including a plurality of ball bumps disposed in a contact pattern compatible with the probe device and semiconductor device further comprises:
a contact pattern compatible with a collapse chips connection packaging.

29. The apparatus claimed in claim 16 wherein the package drawing comprises a generic drawing.

30. The apparatus claimed in claim 16 wherein the package drawing comprises a custom drawing.

31. An interface unit for testing a semiconductor device, comprising:
a first surface wherein a portion of the first surface contains a plurality of ball bumps for interfacing with a probe device;
a second surface opposite the first surface wherein the second surface contains a plurality of contact structures for receiving signals from a testing device; and
a plurality of interconnect layers within the substrate for electronically coupling the plurality of ball bumps on the first surface to the plurality of contact structures in the second surface, such that signals are directly routed between the test device and the probe device and the probe device is directly disposed between the semiconductor device and the interface unit.

32. The interface unit claimed in claim 31 wherein the plurality of ball bumps disposed on the first surface of the interface unit are electrically connected to the probe device during testing.

33. The interface unit claimed in claim 31 wherein the interface unit is formed partly based upon on a package drawing associated with the semiconductor device.

34. The interface unit claimed in claim 31 wherein the interface unit further comprises electrical interconnections that route signals between the test device and the probe device.

35. The interface unit claimed in claim 31 wherein the semiconductor device comprises one or more semiconductor dies.

36. The interface unit claimed in claim 31 wherein the probe device comprises a probe head.

37. The interface unit claimed in claim 31 wherein the interface unit comprises a multi layer substrate.

38. The interface unit claimed in claim 31 wherein the interface unit comprises a printed circuit board.

39. The interface unit claimed in claim 34 wherein the electrical interconnections further comprise:
at least one decoupling capacitor.

40. The interface unit claimed in claim 31 wherein the first surface includes an interconnection pitch that is compatible with the interconnection pitch of bond pads on the semiconductor device.

41. The interface unit claimed in claim 31 wherein the first surface includes an interconnection pitch that is similar or substantially similar to the interconnection pitch of bond pads on the semiconductor device.

42. The interface unit claimed in claim 31 wherein probe device engages with contact pads on the semiconductor device during testing.

43. The interface unit claimed in claim 31 wherein wherein the first surface includes an interconnection pitch that is compatible with the interconnection pitch of bond pads on the semiconductor device further comprises:
a contact pattern compatible with a collapse chips connection packaging.

44. The interface unit claimed in claim 33 wherein the package drawing comprises a generic drawing.

45. The interface unit claimed in claim 33 wherein the package drawing comprises a custom drawing.
